(19) United States
(12) Patent Application Publication
(10) Pub. No.: US 2025/0113591 A1
(43) Pub. Date: Apr. 3, 2025

(54) INTEGRATED CIRCUIT DEVICE WITH LATERALLY DIFFUSED METAL OXIDE SEMICONDUCTOR AND ZENER DIODE

(71) Applicant: Texas Instruments Incorporated, Dallas, TX (US)

(72) Inventor: Alexei Sadovnikov, Sunnyvale, CA (US)

(21) Appl. No.: 18/479,005

(22) Filed: Sep. 30, 2023

(51) Int. Cl. H01L 29/78; H01L 21/265; H01L 29/66

(52) U.S. Cl. CPC H10D 84/153; H01L 21/26513; H10D 30/0281

(57) ABSTRACT

A method forms an integrated circuit, by steps including, in a first implant, forming in a semiconductor substrate a first and second region of a first semiconductor type, each of the first and second region having a first dopant concentration; in a second implant, forming in the semiconductor substrate a third and fourth region of the first semiconductor type, the third region at least partially overlapping the first region and the fourth region at least partially overlapping the second region, each of the third and fourth region having a second dopant concentration different than the first dopant concentration; forming a transistor source within the first and third regions; and forming one of a diode anode or a diode cathode in the second and fourth regions.

### CROSS-REFERENCE TO RELATED APPLICATION

Not applicable.

### TECHNICAL AREA

Described examples relate to semiconductor integrated circuits (IC) and fabrication, and more particularly, but not exclusively, to an IC that includes a laterally diffused metal oxide semiconductor (LDMOS) and an integrated Zener diode.

### BACKGROUND

IC fabrication typically considers and balances tradeoffs among a number of factors, including any one or more of IC size, cost, complexity, performance, and yield, among others. These factors can be further complicated when an IC includes differing types of devices, as sometimes an adjustment to a factor, relative to one of those devices, can have a tradeoff impact on another device(s). These tradeoffs may exist, for example, in an IC with both a transistor and a diode, for example presented as an LDMOS device and a Zener diode, respectively. For example, in some ICs, the LDMOS device may be a transistor with a drain positioned away from the transistor gate, so as to permit higher power application and operations. A Zener diode also may be included in such an IC, for example to couple to the transistor in a manner to permit reverse breakdown of the Zener diode, in an instance of increased voltage on the LDMOS transistor, so as to protect against potential damage to the transistor gate oxide.

While the preceding may have implementation in various baseline devices, this document provides examples that may improve on certain of the above concepts, as detailed below.

### SUMMARY

In an example embodiment, a method of forming an integrated circuit is described. The method forms an integrated circuit, by steps including, in a first implant, forming in a semiconductor substrate a first and second region of a first semiconductor type, each of the first and second region having a first dopant concentration; in a second implant, forming in the semiconductor substrate a third and fourth region of the first semiconductor type, the third region at least partially overlapping the first region and the fourth region at least partially overlapping the second region, each of the third and fourth region having a second dopant concentration different than the first dopant concentration; forming a transistor source within the first and third regions; and forming one of a diode anode or a diode cathode in the second and fourth regions.

Other aspects are also described and claimed.

### BRIEF DESCRIPTION OF THE DRAWINGS

FIGS. 1 through 6 and 8 through 9 are partial cross-sectional views representing successive fabrication stages and resultant structures of an IC semiconductor structure.

FIG. 9A shows a schematic equivalent circuit of an example.

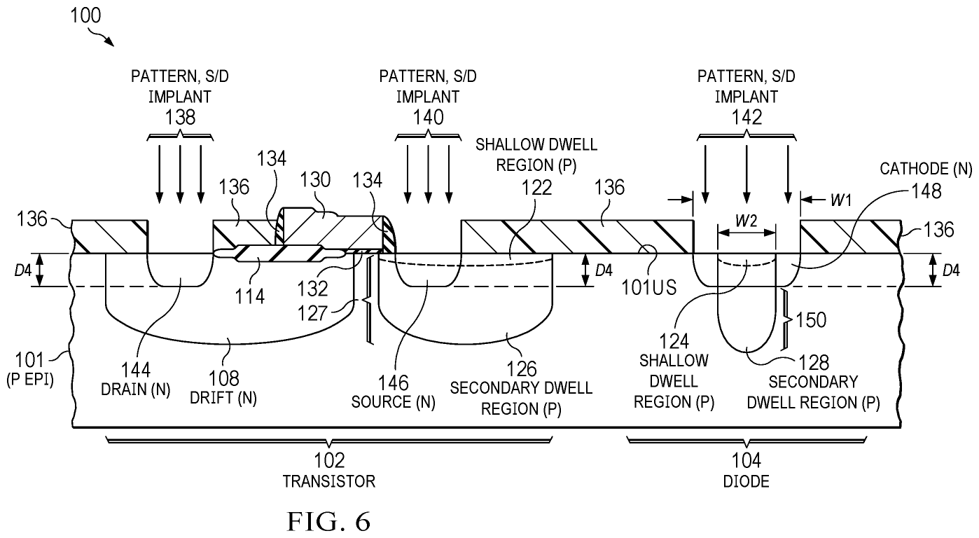

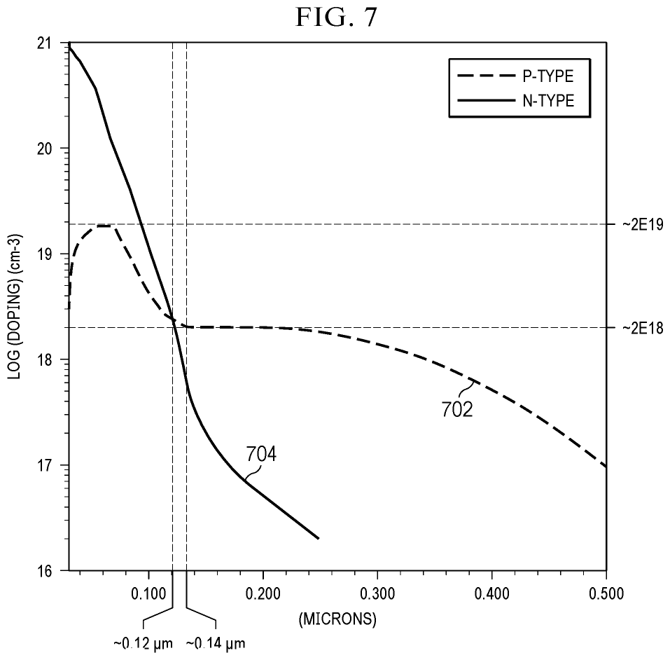

FIG. 7 is a dopant profile plot of selected regions in the FIG. 6 cross-sectional view.

FIG. 10 is a flow diagram of an example method for manufacturing a semiconductor structure.

### DETAILED DESCRIPTION

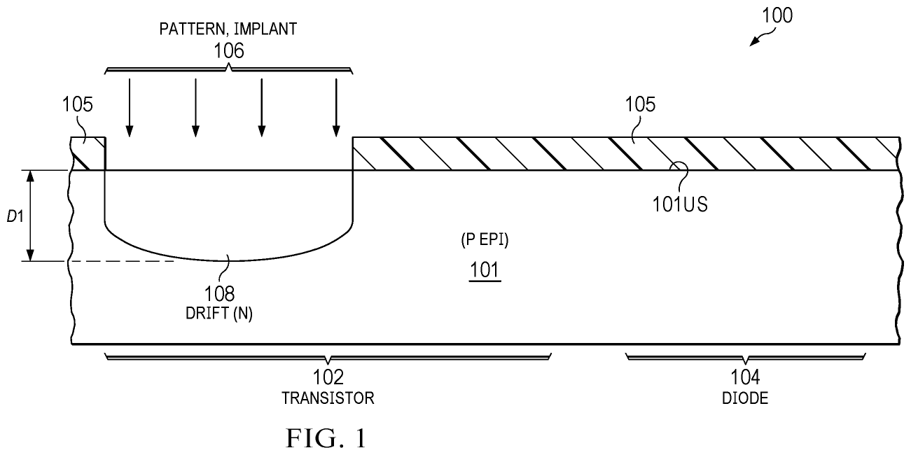

FIGS. 1 through 6 and 8 through 9 are cross-sectional views representing successive fabrication stages and resultant structures of a semiconductor structure 100, e.g. a portion of an IC. Ultimately, the semiconductor structure 100 will include a transistor and diode (e.g., Zener diode), so FIG. 1, and others, show a transistor area 102 and diode area 104, in which the transistor and diode, respectively, are formed. As one example, the IC may provide an LDMOS transistor operating at a voltage greater than associated with traditional planar transistors, for example at 10 volts or more, and a diode may be proximate the LDMOS transistor for voltage-protection purposes, as detailed later. Still further, in addition to the diode, the IC may include numerous other devices (not shown) that function in relation to the transistor. Such devices may be isolated at the substrate level from the structures shown in FIG. 1 (and other later figures), for example via field oxides, formed for example using either a shallow trench isolation (STI) or local oxidation of silicon (LOCOS) process, and may be connected at an interconnect level with the structures shown in FIG. 1.

Starting with FIG. 1, the semiconductor structure 100 includes a semiconductor substrate 101, for example as part of a silicon wafer. Such a wafer typically includes multiple locations, each corresponding to a same or different IC on the wafer, so the illustration of FIG. 1 (and later figures) can be repeated in each wafer IC location. The wafer typically provides either a p-type or n-type semiconductor, and the substrate 101 can represent a portion of the bulk wafer or a region (e.g., a well or buried layer) formed in connection with the wafer. In the illustrated example, the substrate 101 is a p-type epitaxial (epi) layer. A resist mask layer 105, for example using a photolithography process as may also be for other masks identified below, is formed over selective locations across a wafer upper surface 101US. The resist mask layer 105 includes an opening 106 in an area where an implant is to be performed. In the illustrated example, such an implant is performed in a portion of the transistor area 102, for example using an n-type dopant and to form a drift region 108, in the substrate 101. The drift region 108 may have a dopant concentration in a range from 3E15/cm³ to 1E17/cm³, and a maximum depth D1 (shown in the vertical dimension), extending from the upper surface 101US and into the substrate 101, in a range of 0.2 μm to 2 μm.

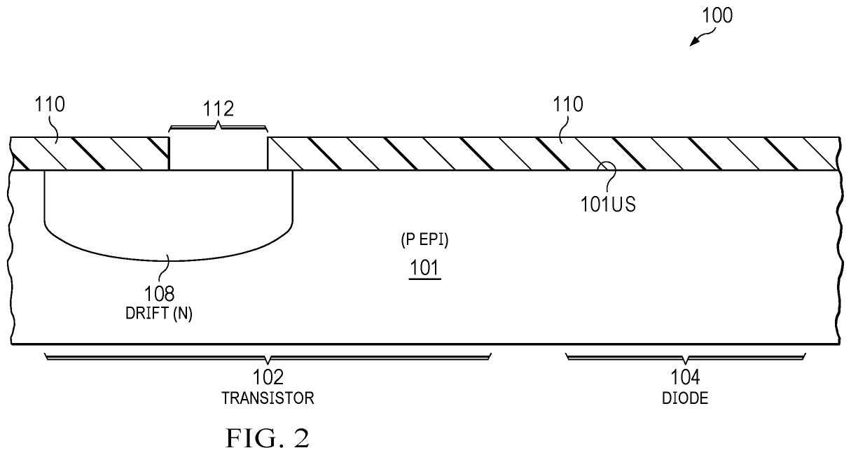

In FIG. 2, the FIG. 1 resist mask layer 105 has been removed. Thereafter a hard mask 110 is formed over a selective location(s) of the upper surface 101US. The hard mask 110 may be formed from a silicon nitride layer patterned using another resist layer (not shown). The hard mask 110 includes an opening 112 above a portion of the drift region 108.

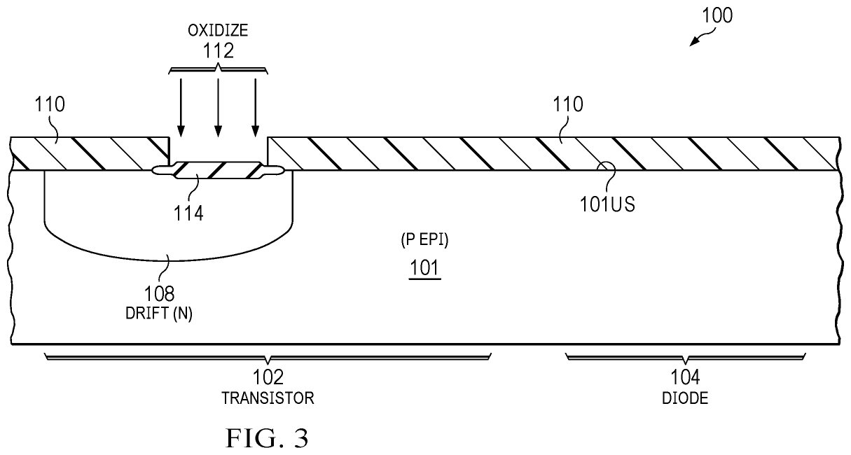

In FIG. 3, a thick LOCOS structure 114 is formed through the opening 112 in the etch mask 110. Generally, the LOCOS structure 114 may be formed by oxidizing the portion of the upper surface 101US that is exposed through the opening 112. As shown, the LOCOS structure 114 may include a central portion having, in the vertical dimension, a greater depth toward its central area, as opposed to in the area around its lateral or peripheral edges which form what is sometimes referred to as “bird's beak.”

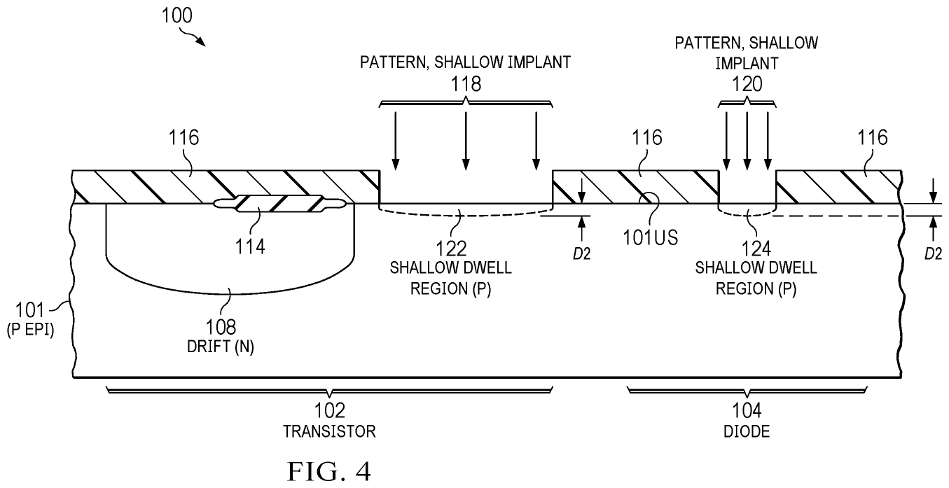

In FIG. 4, the FIG. 3 hard mask 110 has been removed. Thereafter a resist implant mask 116 is formed over a selective location(s) of the upper surface 101US. The resist implant mask 116 includes a first opening 118 above a portion of the transistor area 102, but laterally spaced apart from the drift region 108. The resist implant mask 116 also includes a second opening 120 above a portion of the diode area 104. An implant is performed through both the first and second openings 118 and 120, using a dopant type that is opposite of that used for the drift region 108. Accordingly, in the present example in which the drift region 108 is n-type, then the FIG. 4 implant is p-type, for example using boron. Further, the result of the FIG. 4 implant is termed a shallow implant region in that the implant has an implant energy lower than that used for deeper implants (such as the FIG. 1 implant) as might be expected in some examples where a transistor double-diffused well (DWELL) is created. For example, the FIG. 4 implant dose can be in a range from 1.0E14 atoms/cm² to 2.0E14 atoms/cm² (e.g., 1.4E14 atoms/cm²) and at an energy in a range from 5 keV to 10 keV (e.g., 8 keV). The shallow implant forms a shallow DWELL region 122 in the substrate 101 that is generally aligned with the first opening 118, and it also forms a shallow DWELL region 124 in the substrate 101 that is generally aligned with the second opening 120. In an example, each of the shallow DWELL region 122 and the shallow DWELL region 124 is thereby formed concurrently, with a same implant, and with a depth D2 extending into the substrate 101. The depth D2 is selected based on a depth D4 of a subsequently-formed source/drain (see D4, FIG. 6), where D2 is fifty percent (50%) or less of D4. For example, where D4 may be in a range from 0.10 μm to 0.25 μm, then correspondingly and respectively D2 may be in a range from 50 nm to 125 nm.

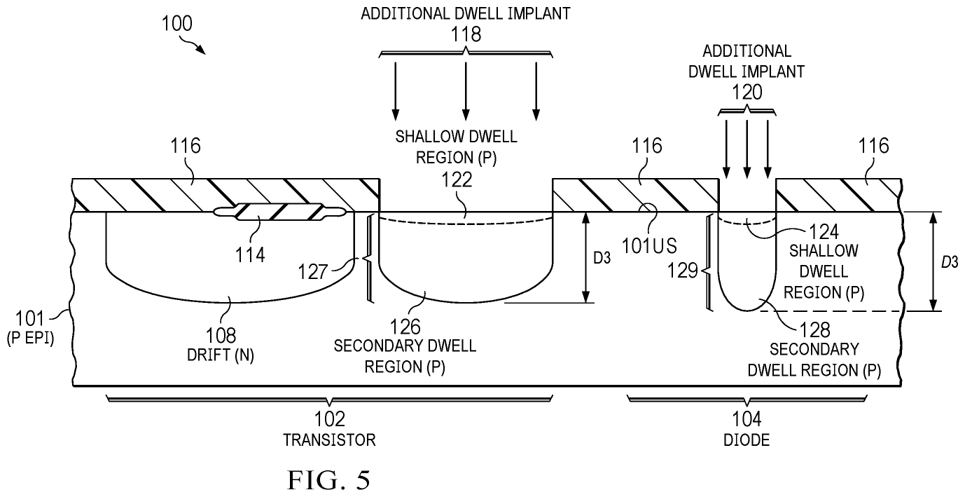

In FIG. 5, the FIG. 4 resist implant mask 116 remains, and a second implant is performed, again through the first opening 118 and the second opening 120. The second implant uses the same dopant conductivity type as used in the FIG. 4 implant, which in the current example is p-type, so as to form additional DWELL regions. Further, in practical implementation, the FIG. 5 implant also may be the same dopant species used in the FIG. 4 implant, although in some instances a different dopant species (still of the same conductivity type, p or n) may be used. The second implant forms a deeper secondary DWELL region 126 below the shallow DWELL region 122, and likewise a deeper secondary DWELL region 128 below the shallow DWELL region 124. Further, the second implant uses a greater energy than the first implant. Recall from FIG. 4 that its implant targets a resultant device with a depth D2, to be less than (shallower) than a later-formed depth D4, of later-formed transistor source/drain regions, e.g. source 144 and drain 146 of FIG. 6. In contrast, the FIG. 5 second implant targets a depth D3 to be greater than (deeper) than a later-formed depth D4 of the transistor source/drain regions. In an example, D3 is at least twice as large as D4, so, again where D4 may be in a range from 0.10 μm to 0.25 μm, then correspondingly and respectively D3 may be in a range from at least 0.2 μm to 0.5 μm, or greater. The second implant uses doses and energies consistent with these goals. For example, where the FIG. 4 first implant dose is 1.0E14 atoms/cm² to 2.0E14 atoms/cm² (e.g., 1.4E14 atoms/cm²) and at an energy in a range from 5 keV to 10 keV (e.g., 8 keV), then the FIG. 5 second implant may have a lower dose and a higher energy, e.g. correspondingly and respectively in a range of 1E13 atoms/cm² to 6E13 atoms/cm², and at an energy in a range from 20 keV to 50 keV (e.g., 3E13 atoms/cm² at an energy of 32 keV). Accordingly, in combination, the shallow DWELL region 122 and the deeper secondary DWELL region 126 provide a DWELL 127 for the transistor area 102, and the shallow DWELL region 124 and the deeper secondary DWELL region 128 provide a DWELL 129 for the diode area 104. In an example, each of the DWELL 127 for the transistor area 102 and the DWELL 129 for the diode area 104 is thereby formed concurrently, with a same implant, and with the depth D3, as further described later in connection with FIG. 7.

In FIG. 6, the FIG. 5 resist implant mask 116 has been removed and a transistor gate poly 130 and related structures have been formed, where the transistor gate poly 130 is so named as it may be formed from polysilicon to provide a conductor. Relatedly, a thin gate insulator 132 has been formed and abuts a portion of the LOCOS structure 114 and extends laterally along a portion of the upper surface 101US, for example beyond the vertical edge of the drift region 108. The thin gate insulator 132 may be formed by growing or depositing an insulator, such as an oxide, over exposed portions of the upper surface 101US and forming a layer of polysilicon thereover. The polysilicon layer and the insulator may then be patterned to form a gate structure including, the transistor gate poly 130 that overlaps the thin gate insulator 132 and a portion of the gate oxide structure 114. Accordingly, one vertical end of the transistor gate poly 130 provides a first sidewall above the LOCOS structure 114, and the other vertical end provides a second sidewall positioned laterally beyond the vertical edge of the drift region 108. The transistor gate poly 130 may be formed by deposition of polysilicon followed by a pattern/etching to the desired structure/position. The deposited polysilicon also may be in-situ or subsequently doped. Thereafter, gate sidewall spacers 134 are formed along the first and second sidewalls of the transistor gate poly 130, for example by formation of an oxide layer above the transistor gate conductor, followed by an appropriate etch so as to leave remaining portions of the oxide later as the gate sidewall spacers 134. Lastly, note that the implants of FIGS. 5 and 6 are shown in an order of first, a shallow implant followed by second, a deeper implant, but in another example this order may be reversed.

After the transistor gate poly 130 and related structures are formed, a resist implant mask 136 is formed by patterning a resist layer over a selective location(s) of the upper surface 101US. The resist implant mask 136 includes a first and second opening 138 and 140 above respective portions of the transistor area 102, with the first opening 138 being above the drift region 108 and the second opening 140 being above both the shallow DWELL region 122 and the secondary DWELL region 126. The resist implant mask 136 also includes a third opening 142 above a portion of the diode area 104 and, more particularly, having a lateral width W1 greater than a width W2 of the shallow DWELL region 124. A source/drain implant is performed through all of the first, second, and third openings 138, 140, and 142, using a dopant type that the same as that for the drift region 108. The source/drain implant may be referred to as an NSD implant, that is, implanting n-type dopant to provide a source/drain functionality of the LDMOS transistor area 102. Accordingly, in the present example in which the drift region 108 is n-type, then the FIG. 6 implant also is n-type, for example using arsenic (or phosphorous or antimony). For example, the FIG. 6 implant can be at 1.0E15 to 1.6E15 atoms/cm² and at an energy from 20 to 30 keV. Further, the FIG. 6 implant is termed a source/drain implant, in that for the transistor area 102, the implant creates a drain region 144 in the drift region 108 and a source region 146 in a portion of the shallow DWELL region 122 and the secondary DWELL region 126, which are both p-type regions that are counterdoped by the FIG. 6 n-type implant. In addition, the n-type source/drain implant forms a region, through the third opening 142 and extending into the substrate 101, termed a cathode region 148, sometimes referred to as a first diode terminal, insofar as the n-type dopant counterdopes the entirety of the p-type shallow DWELL region 124, and an upper portion of the p-type secondary DWELL region 128. Further, because the width W1 exceeds W2 (the upper width of the DWELL that includes the shallow DWELL region 124 and the secondary DWELL region 128), then the cathode region 148 likewise has a larger surface width than the remaining p-type portions of those DWELL regions 124 and 128. In an example, the width W1 is in a range from 0.2 μm to 0.5 μm, while the width W2 is in a range from 1.0 μm to 5.0 μm. Further, note that the cathode region 148 is identified as such because the FIG. 6 counterdoping implant (n-type) creates a region in which electrons are the majority carrier (n-type), thereby forming a cathode relative to the p-type atoms in the remaining (and deeper) portion of the secondary DWELL region 128, which is not reached by the FIG. 6 n-type implant. Accordingly, that remaining and deeper portion forms a diode vertical anode region 150, relative to the cathode region 148. Lastly, in an example, each of the drain region 144, the source region 146, and the cathode region 148 is thereby formed concurrently, with a same implant, and with a depth D4 that exceeds D2, that is, the depth of the FIG. 4 shallow implant; accordingly, for example, with respect to the diode area 104, the cathode region 148 entirely covers and extends beyond and below the shallow DWELL region 124. Additional details relating to the FIG. 6 implant effects are further described below in connection with FIG. 7.

FIG. 7 is a dopant profile diagram 700 of the FIG. 6 DWELL regions, illustrating a non-limiting example of the doping concentration of such regions according to depth extending into (vertically in FIG. 6) the substrate 101 and starting from the upper surface 101US. The diagram 700 indicates depth along its horizontal axis, and doping concentration (in atoms/cm³, logarithmically scaled) along its vertical axis. The diagram 700 includes a p-type dopant plot 702 and an n-type dopant plot 704, each representing the respective dopant type concentration within the FIG. 6 shallow DWELL regions 122 and 124 and the secondary DWELL regions 126 and 128.

The p-type dopant plot 702 demonstrates a notable change in dopant concentration at a depth of approximately 0.12 μm. At relatively smaller depths, for example from the upper surface 101US (0 μm) to a depth of approximately 0.12 μm, the p-type dopant plot 702 depicts the highest levels of p-type dopant, in the DWELL regions. At these smaller depths, the p-type dopants peak at a maximum of approximately 2E19 atoms/cm³, including a starting point at the upper surface 101US with an initial concentration ranging from approximately 3E18 atoms/cm³ to approximately 2E19 atoms/cm³ between the surface and about 0.10 μm, followed by a decreasing concentration to approximately 2.3E18 atoms/cm³ at a depth of 0.12 μm and 2E18 atoms/cm³ at a depth of 0.14 μm. Accordingly, these relatively higher concentrations of p-type dopant represent primarily the doping from the FIG. 4 higher-dose/lower-energy dopant formation of the shallow DWELL regions 122 and 124, as further augmented by the lower-dose/higher-energy formation of the FIG. 5 secondary DWELL regions 126 and 128. At depths greater than approximately 0.12 μm, the p-type plot 702 shows that the concentration of p-type dopants decreases gradually with increasing depth, albeit at lower concentrations—for example with a maximum concentration at least 10 times lower, for example 50 times lower, than the peak between the surface and 0.12 μm depth—to at least a depth of 0.5 μm, with the depth ultimately continuing to the depth D3, introduced above.

The n-type dopant plot 704 demonstrates the dopant concentration resulting from the single source/drain type implant that forms the drain and source regions 144 and 146, and that concurrently also forms the cathode region 148. Inasmuch as the implant step used for that n-type doping uses a relatively low implant energy, the plot 704 provides a highest dose at the upper surface 101US, which declines from that point to a depth of 0.25 μm, which is approximately D4, as introduced above.

Given the preceding, note that the two-implant steps (FIGS. 4 and 5) of p-type dopant provide a plot 702 with attributes relating to each implant, and note further that the p-type dopant plot 702 and n-type dopant plot 704 intersect at an observable depth, where in the illustrated example that depth is approximately 0.12 μm. The intersection point of these plots represents where p-type and n-type materials are equal, that is, the quantity of donors and acceptors are the same, representing a metallurgical junction between the diode cathode region 148 and the diode vertical anode region 150. Accordingly, these attributes further illustrate that on the one hand the FIG. 4 shallow p-type implant may adjust n-type carrier (electron) concentrations in the transistor area 102 for purposes of adjusting transistor threshold voltage as relating to the source region 146 within its DWELL, while the FIG. 5 additional p-type implant may further augment the DWELL by increasing the amount of p-type dopants at greater depths, so as to adjust the point where the p-type dopant plot 702 and n-type dopant plot 704 intersect. Particularly, the FIG. 5 additional higher-energy p-type implant doping concentration is considerably less than the FIG. 4 shallow implant doping concentration—for example by a factor of 10 to 100-so as to adjust the metallurgical junction. Stated alternatively, this additional adjustability permits a corresponding adjustment of the reverse breakdown voltage between the cathode region 148 and the diode vertical anode region 150. Accordingly, the shallow implant may achieve a relatively high dopant concentration in the transistor channel of the transistor DWELL and thereby obtain a favorable (e.g., higher) transistor threshold voltage, while the additional implant, at a lower concentration and greater depths in the DWELLs, may favorably increase the breakdown voltage in the diode DWELL, as compared to what could result were a higher concentration used in a single DWELL implant for the entire DWELL. Further, the desirable diode breakdown voltage is achievable without unduly lowering the transistor threshold voltage.

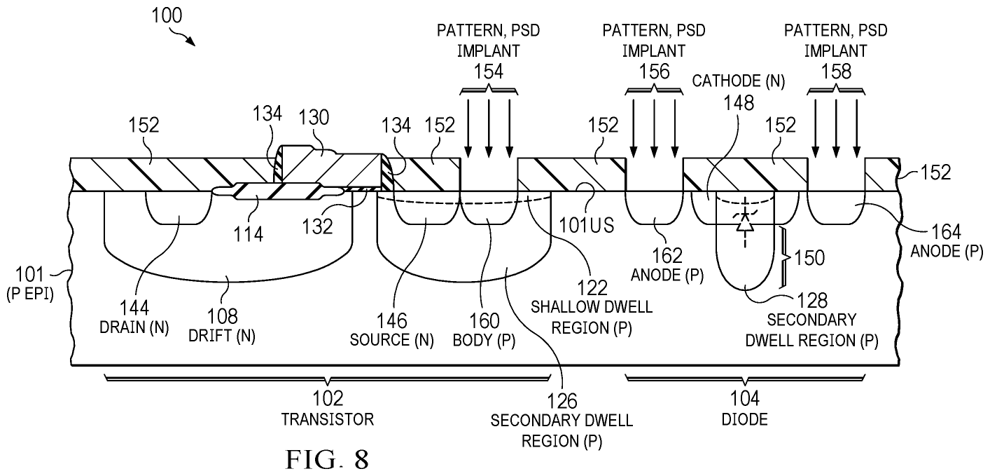

In FIG. 8, the FIG. 6 implant mask 136 has been removed. Thereafter an resist implant mask 152 is formed over selective location(s) of the upper surface 101US by patterning another resist layer. The resist implant mask 152 includes a first opening 154 above the shallow DWELL region 122, laterally spaced apart and having a vertical edge potentially aligned with a vertical edge of the source region 146. The resist implant mask 152 also includes second and third openings 156 and 158, each above a portion of the diode area 104 and laterally displaced outwardly from the diode vertical anode region 150 (from a plan view, not shown) the second and third openings 156, 158 may combine to surround the diode vertical anode region 150. An implant is performed through all of the first, second, and third openings 154, 156, and 158, using a semiconductor type that is opposite of that for the drain and source regions 144 and 146. Accordingly, in the present example in which the drain and source regions 144 and 146 are n-type, then the FIG. 8 implant is p-type, again for example using boron. The FIG. 8 implant can be in a range from at 1E15 atoms/cm² to 10E15 atoms/cm² and at an energy in a range from 5 keV to 10 keV. As a result, the p-type implant forms a body contact 160 in the shallow DWELL region 122 and the secondary DWELL region 126, that may be biased to apply a bias to the transistor DWELL that includes the shallow DWELL region 122 and the secondary DWELL region 126. Because of the formation of the p-type body contact 160, the FIG. 8 implant may be referred to as a PSD implant, that is, implanting p-type dopant and in connection with completion of the source/drain functionality of the LDMOS transistor of the transistor area 102. (The same FIG. 8 p-type implant also forms lateral anode contacts 162 and 164, sometimes referred to as second diode terminals, displaced laterally outward from the cathode region 148. Note that the lateral anode contacts 162 and 164 are identified as part of the anode structure for the diode 104, as they may electrically communicate via a same conductivity type (e.g., p-type) through the p-type epi layer of the substrate 101 with the diode vertical anode region 150.

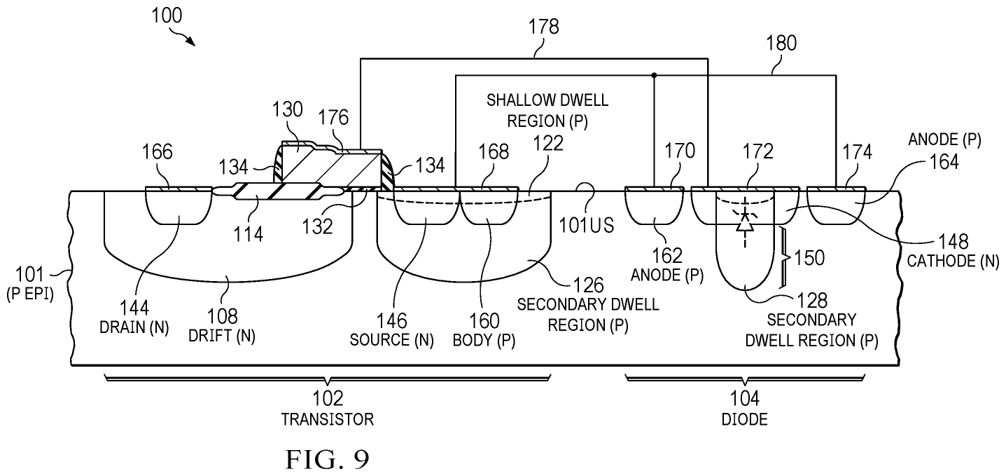

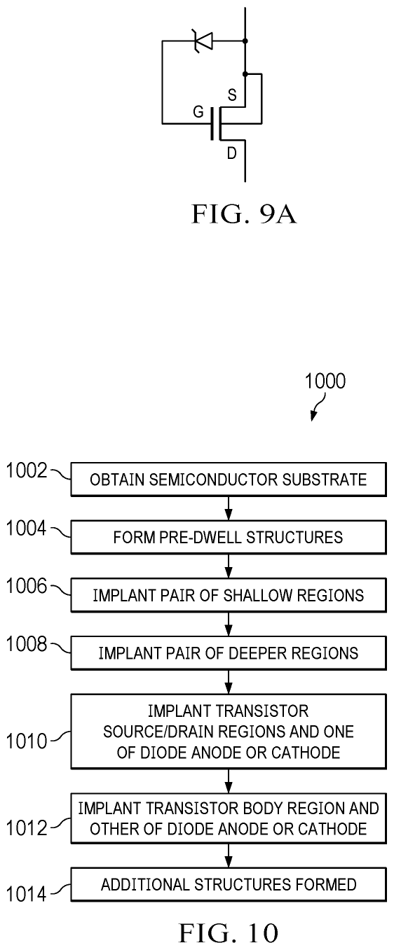

In FIG. 9, the FIG. 8 etch mask 152 has been removed. Thereafter, connections may be made to the transistor in the transistor area 102 and to the diode in the diode area 104, either as between the devices or to other devices. By example, FIG. 9 diagrammatically illustrates electrical connections between the transistor area 102 and the diode area 104, although in other instances the diode may be biased independently of the transistor. In the illustrated example, after the FIG. 8 semiconductor structure 100 is complete, additional steps may be implemented to achieve such electrical connections. For example, silicide conductive regions 166, 168, 170, 172, 174 and 176 are formed along selected semiconductor surfaces, for example respectively and laterally along surfaces of the drain region 144, the source region 146 and the body contact 160 (connected to each other), each of the lateral anode contacts 162 and 164, the cathode region 148 and the gate poly 130. Additional electrical connections may be made, for example through metal layers and metal vias (not shown), formed generally atop the structures shown in FIG. 9, and with contact to appropriate ones of the silicide conductive regions. An example of such electrical connections is shown schematically in FIG. 9, with a first connection 178 between the transistor gate poly 130 and cathode contact 148, and with a second connection 180 between the lateral anode contacts 162 and 164 and the source region 146 and body contact 160. With such connections, as illustrated schematically in FIG. 9A, the overall diode structure in the diode area 104 implements a Zener diode connected in parallel across the gate-to-source path of the transistor in the transistor area 102, with the diode cathode connected to the gate, and the diode anode connected to the source. Accordingly, the reverse breakdown effect of the (e.g., Zener) diode provides a clamping limit of the maximum gate-to-source voltage that will be imposed on the transistor and, more particularly, thereby limiting the voltage drop across the thin gate insulator 132. In other words, as the transistor gate-to-source voltage increases, once it reaches the diode reverse breakdown voltage, the diode will conduct and thereby inhibit (or clamp) any additional increase in the gate voltage. Moreover, because of the favorable transistor structure and method of manufacture described above, the reverse breakdown voltage may be established at a desirable level, without unduly lowering the threshold voltage of the transistor in the transistor area 102.

FIG. 10 is a flow diagram of an example method 1000 that summarizes various of the above-described steps for manufacturing the semiconductor structure 100, for example ultimately providing the structure 100 as shown in FIG. 9. The method 1000 begins in a step 1002, in which the FIG. 1 semiconductor substrate 101 is obtained. The semiconductor substrate 101, at this stage, may be a bare wafer or may have one or more semiconductor features already formed on it. The semiconductor substrate 101 also includes one or more areas in which it is desirable to form a relatively higher voltage transistor and a diode. Next, in a step 1004, pre-DWELL structures are formed. For example, such structures can include the transistor drift region 108 and the LOCOS structure 114. Next, in a step 1006, a pair of shallow implant regions are formed, a first for a portion of the transistor DWELL (e.g., shallow DWELL region 122) and a second for a portion of a diode DWELL (e.g., shallow DWELL region 124). In an example, the pair of shallow implant regions are formed of a same conductivity type and with a same implant step. Next, in a step 1008, a pair of deeper secondary implant regions are formed, a first for a portion of the transistor DWELL (e.g., deeper secondary DWELL region 126) and a second for a portion of a diode DWELL (e.g., deeper secondary DWELL region 128). In an example, the pair of deeper implant regions are formed of a same conductivity type and with a same implant step as the shallow regions from the step 1006, but the step 1008 regions have a lesser dopant concentration. Next, in a step 1010, a first source/drain implant forms source/drain regions for the transistor and concurrently forms a first of either a cathode or anode for the diode, e.g. a cathode for an NSD implant or an anode for a PSD implant. In an example, the first source/drain implant uses processes (dose and energy) so that the source/drain regions, and the anode or cathode, are deeper than the step 1006 shallow regions, but shallower than the step 1008 deeper regions. Next, in a step 1012, a second source/drain (PSD for an n-channel transistor, NSD for a p-channel transistor) implant forms a body contact for the transistor and concurrently the other of either the cathode contact or anode contact for the diode. After step 1012, as shown generally in a step 1014, additional structures may be formed, in connection with the transistor, diode, and interconnections to these and other devices associated with the step 1002 semiconductor substrate.

From the above, one skilled in the art will appreciate that examples are provided for semiconductor IC fabrication, for example with respect to an IC that includes a relatively higher voltage transistor and a diode, which are formed at least in part using concurrent processing steps. Such examples provide various benefits, some of which are described above and including still others. For example, examples may implement a transistor and diode, both of which have DWELL structures, and where those structures are formed during a same implant step and with a single mask common to the structures and through which multiple implants are performed. Accordingly, each the transistor threshold voltage and the diode breakdown voltage may be favorably adjusted, without the use, for example, of an additional mask directed to only one or the other of these attributes. These benefits may be realized for more complex structures, of for multiple devices on the same substrate (and IC), thereby realizing scaled improvement across the device. Still additional modifications are possible in the described embodiments, and other embodiments are possible, within the scope of the following claims.

What is claimed is:

1. A method of forming an integrated circuit, comprising:
in a first implant, forming in a semiconductor substrate a first and second region of a first semiconductor type, each of the first and second region having a first dopant concentration;
in a second implant, forming in the semiconductor substrate a third and fourth region of the first semiconductor type, the third region at least partially overlapping the first region and the fourth region at least partially overlapping the second region, each of the third and fourth region having a second dopant concentration different than the first dopant concentration;
forming a transistor source within the first and third regions; and
forming one of a diode anode or a diode cathode in the second and fourth regions.

2. The method of claim 1, wherein a third implant step comprises the forming a transistor source and the forming one of a diode anode or a diode cathode.

3. The method of claim 1:
wherein the transistor source extends a first depth from a surface of the semiconductor substrate into the semiconductor substrate; and
wherein the first region extends a second depth from the surface of the semiconductor substrate into the semiconductor substrate, the second depth being no greater than fifty percent of the first depth.

4. The method of claim 3, wherein the first depth is in a range from 0.10 μm to 0.25 μm.

5. The method of claim 1:
wherein the transistor source extends a first depth from a surface of the semiconductor substrate into the semiconductor substrate;
wherein the first region extends a second depth from the surface of the semiconductor substrate into the semiconductor substrate, the second depth being no greater than fifty percent of the first depth; and
wherein the third region extends a third depth from the surface of the semiconductor substrate into the semiconductor substrate, the third depth being at least twice the first depth.

6. The method of claim 5, wherein the first depth is in a range from 0.10 μm to 0.25 μm.

7. The method of claim 1, in addition to forming one of a diode anode or a diode cathode, forming the other of the diode anode or a diode cathode in the semiconductor substrate, and wherein a reverse bias breakdown voltage, between the diode anode and the diode cathode, is responsive to an intersection depth between the first dopant concentration and the second dopant concentration.

8. The method of claim 1:
wherein the second region has a first width in a lateral dimension relative to the semiconductor substrate; and
wherein the other of the diode anode or a diode cathode has a second width in the lateral dimension relative to the semiconductor substrate, wherein the second width is greater than the first width.

9. The method of claim 1 and further comprising:
forming a transistor drain and transistor channel in the semiconductor substrate and a transistor gate in a fixed position relative to the semiconductor substrate; and
in addition to forming one of a diode anode or a diode cathode, forming the other of the diode anode or a diode cathode in the semiconductor substrate.

10. The method of claim 9:
wherein a transistor threshold voltage, relative to the transistor source and the transistor gate, is responsive to the second dopant concentration; and
wherein a reverse bias breakdown voltage, between the diode anode and the diode cathode, is responsive to an intersection point between the first dopant concentration and the second dopant concentration.

11. The method of claim 1, wherein the first semiconductor type includes boron.

12. The method of claim 11, wherein the transistor source is formed from an n-type semiconductor.

13. The method of claim 12, wherein the transistor source is formed from arsenic.

14. The method of claim 1, wherein the forming one of a diode anode or a diode cathode forms at least a portion of the diode anode.

15. The method of claim 11 and further comprising forming a coupling from the transistor source to the diode anode.

16. The method of claim 1 wherein the second dopant concentration has a peak value less than 10% of a peak value of the first dopant concentration.

17. A method of forming an integrated circuit, comprising:
concurrently implanting a first dopant of a first conductivity type in first and second regions extending into a semiconductor substrate having the first semiconductor type, the first and second regions having a first dopant concentration;
concurrently implanting a second dopant of the first conductivity type in a third region overlapping the first region and in a fourth region overlapping the second region, the third and fourth regions being deeper than the first and second regions and having a lower dopant concentration than the first and second regions;
concurrently implanting a third dopant of an opposite second conductivity type in a fifth region overlapping the first and third regions and in a sixth region overlapping the second and fourth regions, the fifth region implementing a transistor source and the sixth region implementing a first terminal of a diode;
implanting a third dopant of the first conductivity type in a seventh region spaced apart from the sixth region and extending into the semiconductor substrate and implementing a second terminal of the diode;
forming a transistor gate over the semiconductor substrate adjacent the transistor source; and
electrically connecting the transistor source to the second diode terminal and the transistor gate to the first diode terminal.

18. The method of claim 17 wherein the first conductivity type is p-type and the second conductivity type is n-type.

19. The method of claim 17 wherein the sixth region has a peak concentration of first conductivity type dopants no greater than 10% of a peak concentration of second conductivity type dopants.

20. An integrated circuit, comprising:
a substrate;
a transistor positioned at least in part in the substrate, and comprising a transistor well structure extending into the substrate from a surface of the substrate, the transistor well structure including a first region from the surface of the substrate to a first depth and having a first peak dopant concentration and a second region from the surface of the substrate to a second depth, greater than the first depth, and having a second peak dopant concentration less than the first peak dopant concentration; and
a diode positioned at least in part in the substrate, and comprising a diode well structure extending into the substrate from the surface of the substrate, the diode well structure including a third region from the surface of the substrate to the first depth and having the first peak dopant concentration and a fourth region from the surface of the substrate to the second depth and having the second peak dopant concentration.
